(19) United States
(12) Patent Application Publication
(10) Pub. No.: US 2026/0358436 A1
(43) Pub. Date: Nov. 12, 2026

(54) BATTERY DIAGNOSIS APPARATUS AND METHOD FOR DETECTING MICRO INTERNAL SHORT CIRCUIT

(71) Applicants: Hyundai Motor Company, Seoul (KR); Kia Corporation, Seoul (KR)

(72) Inventor: Sungho Kim, Hwaseong (KR)

(21) Appl. No.: 19/335,971

(22) Filed: Sep. 22, 2025

(30) Foreign Application Priority Data
May 12, 2025 (KR) 10-2025-0061125

(51) Int. Cl. G01R 31/52; B60L 58/12; B60L 58/18; G01R 31/3835; G01R 31/392; G01R 31/396

(52) U.S. Cl. CPC G01R 31/52; B60L 58/12; B60L 58/18; G01R 31/3835; G01R 31/392; G01R 31/396; B60L 2240/545; B60L 2240/547

(57) ABSTRACT

The present disclosure relates to a battery diagnosis apparatus and a method for diagnosing a battery cell in which a micro internal short circuit has occurred during a cell balancing inactive period. A battery diagnosis apparatus according to one embodiment of the present disclosure may include a battery cell diagnosis unit configured to diagnose a micro internal short circuit in each of a plurality of battery cells based on voltage variations of reference battery cells among the plurality of battery cells.

### CROSS-REFERENCE TO RELATED APPLICATION

This present application claims, under 35 U.S.C. §119(a), the benefit of Korean Patent Application No. 10-2025-0061125, filed May 12, 2025, in the Korean Intellectual Property Office, the entire disclosure of which is incorporated herein by reference.

### BACKGROUND

### Technical Field

The present disclosure relates to a battery diagnosis apparatus and a method for detecting a micro internal short circuit and, more particularly, to a battery diagnosis apparatus and a method for diagnosing a battery cell in which a micro internal short circuit has occurred during a cell balancing inactive period.

### Background

Electric vehicles, being configured to run on battery power, regularly comprise a battery pack configured to provide power. Generally, a battery pack may comprise a plurality of battery cells connected in series and/or in parallel.

A battery cell may comprise a positive electrode current collector, a negative electrode current collector, a separator, an active material, an electrolyte, and the like, and may be configured to perform repeated charging and discharging through electrochemical reactions among these components. Battery cells are designed to have high density and high energy. Therefore, ensuring safety is critical since abnormal behavior may lead to hazardous situations.

Abnormal behavior of battery cells may primarily manifest as voltage deviations between battery cells caused by their abnormal degradation. The voltage deviation between the battery cells may not only reduce battery capacity and lifespan, but also accelerate cell degradation, creating a harmful operating environment.

Therefore, a cell balancing function may be applied to ensure the stability of battery cells. The cell balancing function may be configured to monitor voltage deviations between battery cells and adjust the monitored voltage deviations among the battery cells.

However, when the ignition (IG) switches to an OFF state, a vehicle control unit (VCU), which is responsible for performing the cell balancing function, also turns off, resulting in a cell balancing inactive period. During this period, the cell balancing function may not operate, and voltage deviations between battery cells may not be actively monitored.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

The present disclosure is directed to providing a battery diagnosis apparatus and a method for diagnosing a battery cell in which a micro internal short circuit has occurred during a cell balancing inactive period.

In addition, the present disclosure is directed to providing a battery diagnosis apparatus and a method for detecting a micro internal short circuit, which may improve diagnostic sensitivity in diagnosing a micro internal short circuit in a battery cell.

The present disclosure is not limited to what has been described above, and other aspects not mentioned herein will be apparent from the following description to one of ordinary skill in the art to which the present disclosure pertains. Moreover, aspects of the present disclosure may be realized by the means and combinations thereof indicated in claims.

An aspect of the present disclosure may provide a battery diagnosis apparatus including a battery cell diagnosis unit configured to diagnose a micro internal short circuit in each of a plurality of battery cells based on voltage variations of reference battery cells among the plurality of battery cells.

The battery cell diagnosis unit may be configured to diagnose a micro internal short circuit in each of the plurality of battery cells based on a difference between a voltage variation of each of the plurality of battery cells and an average value of voltage variations of the reference battery cells.

The battery cell diagnosis unit may be configured to diagnose a battery cell among the plurality of battery cells as having a micro internal short circuit, based on a difference between the voltage variation of the battery cell and the average value of the voltage variations of the reference battery cells exceeding a diagnostic threshold, and on repeated detection, at least a target number of times, of the difference exceeding the diagnostic threshold.

The reference battery cells may include diagnostic reference cells, which may be defined as remaining battery cells other than an abnormal battery cell that has the greatest voltage variation among the plurality of battery cells.

The battery diagnosis apparatus may further include a voltage variation determination unit configured to determine a voltage variation for each battery cell as a difference between a first voltage of each battery cell, which is an open circuit voltage (OCV) measured in an ignition-off (IG off) state, and a second voltage of each battery cell, which is an open circuit voltage (OCV) measured in an ignition-on (IG on) state.

The voltage variation determination unit may be configured to store, as the first voltage, an OCV measured when the vehicle control unit (VCU) first wakes up after transitioning to an off state in response to ignition-off (IG off).

The voltage variation determination unit may be configured to initialize the first voltage and the second voltage based on a determination, in the ignition-on (IG on) state, that the OCV stored as the first voltage does not exist, and to store, as the first voltage, an OCV measured in a next ignition-off (IG off) state.

The voltage variation determination unit may be configured to store, as the second voltage, an OCV measured in an ignition-on (IG on) state, based on a state of charge (SOC) being equal to or above a target level and a temperature being equal to or above a target temperature.

Another aspect of the present disclosure may provide a battery diagnosis apparatus including a memory having instructions stored thereon, and a processor configured to, by executing the instructions, diagnose a micro internal short circuit in each of a plurality of battery cells based on voltage variations of reference battery cells among the plurality of battery cells.

Still another aspect of the present disclosure may provide a method for detecting a micro internal short circuit including diagnosing a micro internal short circuit in each of a plurality of battery cells based on voltage variations of reference battery cells among the plurality of battery cells.

The diagnosing a micro internal short circuit in each of the plurality of battery cells may include diagnosing a micro internal short circuit in each of the plurality of battery cells based on a difference between a voltage variation of each of the plurality of battery cells and an average value of voltage variations of the reference battery cells.

The diagnosing a micro internal short circuit in each of the plurality of battery cells may include diagnosing a battery cell among the plurality of battery cells as having a micro internal short circuit, based on a difference between the voltage variation of the battery cell and the average value of the voltage variations of the reference battery cells exceeding a diagnostic threshold, and on repeated detection, at least a target number of times, of the difference exceeding the diagnostic threshold.

The reference battery cells may include diagnostic reference cells, which may be defined as remaining battery cells other than an abnormal battery cell that has the greatest voltage variation among the plurality of battery cells.

The method for detecting a micro internal short circuit may further include determining a voltage variation for each battery cell as a difference between a first voltage of each battery cell, which is an open circuit voltage (OCV) measured in an ignition-off (IG off) state, and a second voltage of each battery cell, which is an OCV measured in an ignition-on (IG on) state.

The first voltage may include an OCV measured when a vehicle control unit (VCU) first wakes up after transitioning to an off state in response to ignition-off (IG off).

The first voltage may include an OCV measured in a next ignition-off (IG off) state, based on a determination, in the ignition-on (IG on) state, that the OCV stored as the first voltage does not exist.

The second voltage may include an OCV measured in the ignition-on (IG on) state, based on a state of charge (SOC) being equal to or above a target level and a temperature being equal to or above a target temperature.

According to embodiments of the present disclosure, a micro internal short circuit in each of a plurality of battery cells may be diagnosed by comparing a voltage variation of each of the plurality of battery cells with a reference value based on voltage variations of the plurality of battery cells.

This may allow for diagnosing a micro internal short circuit in each of the plurality of battery cells, during a cell balancing inactive period.

In addition, according to embodiments of the present disclosure, in the process of diagnosing a micro internal short circuit in each of a plurality of battery cells, a battery cell having the largest voltage variation among the plurality of battery cells may be determined as an abnormal cell. The abnormal cell may be excluded from the diagnostic reference cells for detecting a micro internal short circuit, thereby improving diagnostic sensitivity.

According to an aspect of the present disclosure, a battery diagnosis apparatus is provided. The battery diagnosis apparatus may comprise a computing device comprising a battery cell diagnosis unit configured to diagnose a micro internal short circuit in one or more battery cells, of a plurality of battery cells, when a difference between a voltage variation of a battery cell, of the plurality of battery cells, and an average voltage variation value of one or more diagnostic reference battery cells exceeds a diagnostic threshold value.

According to an exemplary embodiment, the diagnostic threshold may be 3mV.

According to an exemplary embodiment, the battery cell diagnosis unit may be configured to diagnose a battery cell, of the plurality of battery cells as having a micro internal short circuit, when a difference between a voltage variation of the battery cell, of the plurality of battery cells, and the average voltage variation value of the one or more diagnostic reference battery cells exceeding the diagnostic threshold value is detected at least a target number of times.

According to an exemplary embodiment, the battery diagnosis apparatus may comprise the plurality of battery cells.

According to an exemplary embodiment, the reference battery cells may comprise diagnostic reference cells comprising one or more remaining battery cells, other than an abnormal battery cell, that has a greatest voltage variation among the plurality of battery cells.

According to an exemplary embodiment, the computing device may comprise a voltage variation determination unit configured to determine a voltage variation for each battery cell as a difference between a first voltage of each battery cell, which comprises an open circuit voltage (OCV) measured in an ignition-off (IG off) state, and a second voltage of each battery cell, which comprises an open circuit voltage (OCV) measured in an ignition-on (IG on) state.

According to an exemplary embodiment, the voltage variation determination unit may be configured to store, as the first voltage, an OCV measured when the vehicle control unit (VCU) first wakes up after transitioning to an off state in response to ignition-off (IG off).

According to an exemplary embodiment, the voltage variation determination unit may be configured to initialize the first voltage and the second voltage based on a determination, in the ignition-on (IG on) state, that the OCV stored as the first voltage does not exist, and to store, as the first voltage, an OCV measured in a next ignition-off (IG off) state.

According to an exemplary embodiment, the voltage variation determination unit may be configured to store, as the second voltage, an OCV measured in an ignition-on (IG on) state, based on a state of charge (SOC) being equal to or above a target level and a temperature being equal to or above a target temperature.

According to an aspect of the present disclosure, a battery diagnosis apparatus is provided. The battery diagnosis apparatus may comprise a computing device comprising a processor and a memory. The memory may be configured to store instructions that, when executed by the processor, are configured to cause the processor to diagnose a micro internal short circuit in one or more battery cells, of a plurality of battery cells, when a difference between a voltage variation of a battery cell, of the plurality of battery cells, and an average voltage variation value of one or more diagnostic reference battery cells exceeds a diagnostic threshold value.

According to an exemplary embodiment, the battery diagnosis apparatus may comprise the plurality of battery cells.

According to an exemplary embodiment, the computing device may be configured to diagnose a battery cell, of the plurality of battery cells as having a micro internal short circuit, when a difference between a voltage variation of the battery cell, of the plurality of battery cells, and the average voltage variation value of the one or more diagnostic reference battery cells exceeding the diagnostic threshold value is detected at least a target number of times.

According to an aspect of the present disclosure, a method for detecting a micro internal short circuit performed by a battery diagnosis apparatus is provided. The method may comprise, using a computing device comprising a processor and a memory, diagnosing a micro internal short circuit in one or more battery cells, of a plurality of battery cells, when a difference between a voltage variation of a battery cell, of the plurality of battery cells, and an average voltage variation value of one or more diagnostic reference battery cells exceeds a diagnostic threshold value.

According to an exemplary embodiment, the diagnostic threshold may be 3mV.

According to an exemplary embodiment, the diagnosing may comprise diagnosing a battery cell among the plurality of battery cells as having a micro internal short circuit, when a difference between a voltage variation of the battery cell, of the plurality of battery cells, and the average voltage variation value of the one or more diagnostic reference battery cells exceeding the diagnostic threshold value is detected at least a target number of times.

According to an exemplary embodiment, the reference battery cells may comprise diagnostic reference cells comprising as remaining battery cells, other than an abnormal battery cell, that has a greatest voltage variation among the plurality of battery cells.

According to an exemplary embodiment, the method may comprise, using the computing device, determining a voltage variation for each battery cell as a difference between a first voltage of each battery cell, which comprises an open circuit voltage (OCV) measured in an ignition-off (IG off) state, and a second voltage of each battery cell, which comprises an OCV measured in an ignition-on (IG on) state.

According to an exemplary embodiment, the first voltage may comprise an OCV measured when a vehicle control unit (VCU) first wakes up after transitioning to an off state in response to ignition-off (IG off).

According to an exemplary embodiment, the first voltage may comprise an OCV measured in a next ignition-off (IG off) state, based on a determination, in the ignition-on (IG on) state, that the OCV stored as the first voltage does not exist.

According to an exemplary embodiment, the second voltage may comprise an OCV measured in the ignition-on (IG on) state, based on a state of charge (SOC) being equal to or above a target level and a temperature being equal to or above a target temperature.

### BRIEF DESCRIPTION OF THE DRAWINGS

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 illustrates a diagram illustrating a structure of a battery diagnosis environment, according to an exemplary embodiment of the present disclosure.

FIG. 2 illustrates a block diagram illustrating a configuration of a battery diagnosis apparatus, according to an exemplary embodiment of the present disclosure.

FIG. 3 illustrates a diagram exemplarily illustrating voltage variation values for a plurality of battery cells, according to an exemplary embodiment of the present disclosure.

FIG. 4 illustrates a diagram exemplarily illustrating the distribution of voltage variations for a plurality of battery cells, according to an exemplary embodiment of the present disclosure.

FIG. 5 illustrates a diagram exemplarily illustrating an average value of voltage variations for diagnostic reference cells, according to an exemplary embodiment of the present disclosure.

FIG. 6 illustrates a flowchart illustrating a method for detecting a micro internal short circuit, according to an exemplary embodiment of the present disclosure.

### DETAILED DESCRIPTION

Hereinafter, exemplary embodiments disclosed in the present document will be described in detail with reference to the accompanying drawings. Like reference numerals designate like elements, and redundant descriptions thereof will be omitted. Further, such as "module" and a "unit", suffixes for components used in the following description are given or mixed and used by considering easiness in preparing a specification and do not have a meaning or role distinguished from each other in themselves. In addition, in describing an embodiment disclosed in the present document, if it is determined that a detailed description of a related art incorporated herein unnecessarily obscure the gist of the embodiment, the detailed description thereof will be omitted. Furthermore, it should be understood that the appended drawings are intended only to help understand embodiments disclosed in the present document and do not limit the technical principles and scope of the present disclosure; rather, it should be understood that the appended drawings include all of the modifications, equivalents or substitutes described by the technical principles and belonging to the technical scope of the present disclosure.

Although the terms first, second, third, and the like may be used herein to describe various elements, components, regions, layers, and/or sections, these elements, components, regions, layers, and/or sections should not be limited by these terms. These terms are only used to distinguish one element from another.

When an element or layer is referred to as being "on," "engaged to," "connected to," or "coupled to" another element or layer, it may be directly on, engaged, connected, or coupled to the other element or layer, or intervening elements or layers may be present. In contrast, when an element is referred to as being "directly on," "directly engaged to," "directly connected to," or "directly coupled to" another element or layer, there may be no intervening elements or layers present.

For purposes of this application and the claims, using the exemplary phrase "at least one of: A; B; or C" or "at least one of A, B, or C," the phrase means "at least one A, or at least one B, or at least one C, or any combination of at least one A, at least one B, and at least one C. Further, exemplary phrases, such as "A, B, and C", "A, B, or C", "at least one of A, B, and C", "at least one of A, B, or C", etc. as used herein may mean each listed item or all possible combinations of the listed items. For example, "at least one of A or B" may refer to (1) at least one A; (2) at least one B; or (3) at least one A and at least one B.

The following Detailed Description is merely provided by way of example and not of limitation. Furthermore, there is no intention to be bound by any expressed or implied theory presented in the preceding background or in the following Detailed Description.

Reference will now be made in detail to various exemplary embodiments of the subject matter, examples of which are illustrated in the accompanying drawings. While various embodiments are discussed herein, it will be understood that they are not intended to limit to these embodiments. On the contrary, the presented embodiments are intended to cover alternatives, modifications, and equivalents, which may be included within the spirit and scope of the various embodiments as defined by the appended claims. Furthermore, in this Detailed Description, numerous specific details are set forth in order to provide a thorough understanding of embodiments of the present subject matter. However, embodiments may be practiced without these specific details. In other instances, well-known methods, procedures, components, and circuits have not been described in detail as not to unnecessarily obscure aspects of the described embodiments.

Some portions of the detailed descriptions which follow are presented in terms of procedures, logic blocks, processing, and other symbolic representations of operations on data within an electrical device. These descriptions and representations are the means used by those skilled in the data processing arts to most effectively convey the substance of their work to others skilled in the art. In the present application, a procedure, logic block, process, or the like, is conceived to be one or more self-consistent procedures or instructions leading to a desired result. The procedures are those requiring physical manipulations of physical quantities. Usually, although not necessarily, these quantities may take the form of electrical or magnetic signals capable of being stored, transferred, combined, compared, and otherwise manipulated in an electronic system, device, and/or component.

It should be borne in mind, however, that these and similar terms are to be associated with the appropriate physical quantities and are merely convenient labels applied to these quantities. Unless specifically stated otherwise as apparent from the following discussions, it is appreciated that throughout the description of embodiments, discussions utilizing terms such as “determining,” “communicating,” “taking,” “comparing,” “monitoring,” “calibrating,” “estimating,” “initiating,” “providing,” “receiving,” “controlling,” “transmitting,” “isolating,” “generating,” “aligning,” “synchronizing,” “identifying,” “maintaining,” “displaying,” “switching,” or the like, refer to the actions and processes of an electronic item such as: a processor, a sensor processing unit (SPU), a processor of a sensor processing unit, an application processor of an electronic device/system, or the like, or a combination thereof. The item manipulates and transforms data represented as physical (electronic and/or magnetic) quantities within the registers and memories into other data similarly represented as physical quantities within memories or registers or other such information storage, transmission, processing, or display components.

The terminology used herein is for the purpose of describing particular embodiments only and is not intended to be limiting of the disclosure. As used herein, the singular forms "a," "an" and "the" are intended to include the plural forms as well, unless the context clearly indicates otherwise. These terms are merely intended to distinguish one component from another component, and the terms do not limit the nature, sequence or order of the constituent components. It will be further understood that the terms "comprises" and/or "comprising," when used in this specification, specify the presence of stated features, integers, steps, operations, elements, and/or components, but do not preclude the presence or addition of one or more other features, integers, steps, operations, elements, components, and/or groups thereof. As used herein, the term "and/or" includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

It is understood that the term "vehicle" or "vehicular" or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles. In aspects, a vehicle may comprise an internal combustion engine system as disclosed herein.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, logic, circuits, and steps have been described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example device vibration sensing system and/or electronic device described herein may include components other than those shown, including well-known components.

Various techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, perform one or more of the methods described herein. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

Various embodiments described herein may be executed by one or more processors, such as one or more motion processing units (MPUs), sensor processing units (SPUs), host processor(s) or core(s) thereof, digital signal processors (DSPs), general purpose microprocessors, application specific integrated circuits (ASICs), application specific instruction set processors (ASIPs), field programmable gate arrays (FPGAs), a programmable logic controller (PLC), a complex programmable logic device (CPLD), a discrete gate or transistor logic, discrete hardware components, or any combination thereof designed to perform the functions described herein, or other equivalent integrated or discrete logic circuitry. The term “processor,” as used herein may refer to any of the foregoing structures or any other structure suitable for implementation of the techniques described herein. As employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Moreover, processors can exploit nano-scale architectures such as, but not limited to, molecular and quantum-dot based transistors, switches and gates, in order to optimize space usage or enhance performance of user equipment. A processor may also be implemented as a combination of computing processing units.

In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any processor, controller, microcontroller, or state machine. A processor may also be implemented as a combination of computing devices, e.g., a combination of an SPU/MPU and a microprocessor, a plurality of microprocessors, one or more microprocessors in conjunction with an SPU core, MPU core, or any other such configuration. One or more components of an SPU or electronic device described herein may be embodied in the form of one or more of a “chip,” a “package,” an Integrated Circuit (IC).

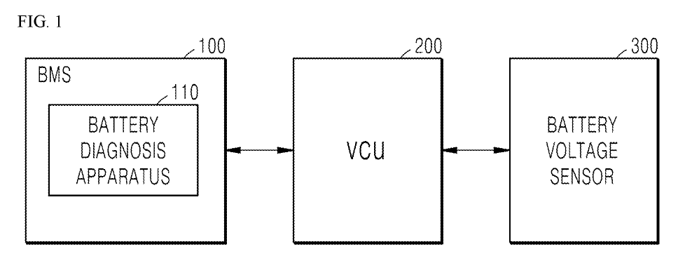

Hereinafter, a battery diagnosis apparatus and a method for detecting a micro internal short circuit according to embodiments of the present disclosure will be described in detail with reference to FIGS. 1-6.

According to an exemplary embodiment, a micro internal short circuit may comprise a localized, generally small, defect within a battery (e.g., a lithium-ion battery or other suitable type of battery). The micro internal short circuit occurs when there is a partial connection between the positive electrodes and negative electrodes of the battery.

Typically, abnormal behavior of battery cells may primarily manifest as voltage deviations between battery cells caused by their abnormal degradation.

The voltage deviations between battery cells may not only reduce battery capacity and lifespan, but also accelerate degradation of battery cells, thereby creating a harmful operating environment.

Therefore, a cell balancing function may be applied to ensure the stability of battery cells. The cell balancing function may be configured to monitor voltage deviations between battery cells and adjust the monitored voltage deviations among the battery cells. However, when the ignition (IG) is switched to an off state, a vehicle control unit (VCU), which is responsible for performing the cell balancing function, may also turn off. In such a situation, the off state of the VCU may lead to a cell balancing inactive period, during which monitoring of voltage deviations between battery cells may be restricted.

In addition, during a vehicle inactivity period (e.g., long-term parking or when the vehicle is left unused) in which both the ignition and the VCU remain off, a cell balancing inactive period may also occur. In such a case, a micro internal short circuit may occur in a battery cell, resulting in self-discharge. This self-discharge may accelerate degradation of the battery cell over time and threaten the stability of the battery cell. Therefore, a countermeasure may be required to address this issue.

According to an exemplary embodiment of the present disclosure, a method for enabling and/or facilitating diagnosis of a micro internal short circuit in a battery cell, even during a cell balancing inactive period caused by the off state of the VCU, is provided.

FIG. 1 is a diagram exemplarily illustrating a structure of a battery diagnosis environment, according to an exemplary embodiment of the present disclosure.

Referring to FIG. 1, a battery diagnosis environment, according to an exemplary embodiment of the present disclosure, may comprise a battery management system (BMS) 100 that may be configured to communicate with a vehicle control unit (VCU) 200 and monitor voltage variations of a plurality of battery cells within a battery pack through the VCU 200 and a battery voltage sensor 300.

The BMS 100 may comprise a battery diagnosis apparatus 110. The battery diagnosis apparatus 110 may be configured to diagnose a micro internal short circuit in each of a plurality of battery cells based on voltage variations of the plurality of battery cells monitored, during a cell balancing inactive period caused by the off state of the VCU.

The voltage variation of a battery cell may comprise a difference between a voltage of the battery cell measured in an ignition-off (IG off) state and a voltage of the battery cell measured in an ignition-on (IG on) state.

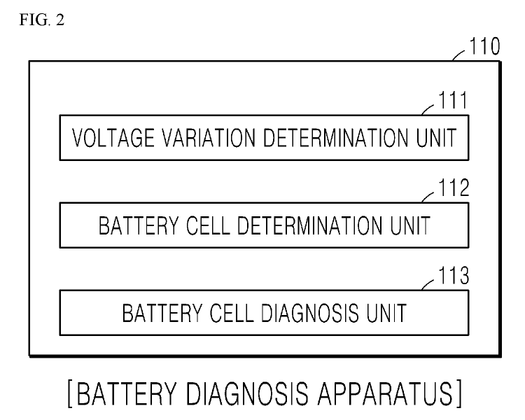

The following describes a battery diagnosis apparatus according to an exemplary embodiment of the present disclosure with reference to FIGS. 2-5.

FIG. 2 is a block diagram illustrating a configuration of a battery diagnosis apparatus 110, according to an exemplary embodiment of the present disclosure.

Referring to FIG. 2, a battery diagnosis apparatus 110, according to an exemplary embodiment of the present disclosure, may comprise a memory having instructions stored thereon and a processor configured to execute the instructions stored in the memory. According to an exemplary embodiment, the battery diagnosis apparatus 110 may comprise and/or be coupled to a computing device configured to perform one or more functions of the battery diagnosis apparatus 110.

The processor, according to an exemplary embodiment of the present disclosure, may comprise a functional configuration comprising a voltage variation determination unit 111, a battery cell determination unit 112, and a battery cell diagnosis unit 113, according to functionalities implemented by executing the instructions.

The battery diagnosis apparatus 110, according to an exemplary embodiment of the present disclosure, may be configured to diagnose a micro internal short circuit in a battery cell, during a cell balancing inactive period, through functional units implemented by the processor as described above. The following provides a more detailed explanation of each functional unit that enables the diagnosis of a micro internal short circuit in the battery cell.

The voltage variation determination unit 111 may be configured to store, as a first voltage, an open circuit voltage (OCV) measured in an ignition-off (IG off) state for each of the plurality of battery cells.

For example, the voltage variation determination unit 111 may be configured to store, as the first voltage, an open circuit voltage (OCV) measured when the vehicle control unit (VCU) first wakes up after transitioning to an off state in response to ignition-off (IG off).

The point in time when the vehicle control unit (VCU) first wakes up after transitioning to the off state corresponds to a moment when battery polarization is minimized, and an open circuit voltage (OCV) is measured at this time to determine the battery's final charging voltage (V_finish). This helps prevent misdiagnosis in the micro internal short circuit detection logic due to voltage differences caused by the battery polarization.

The voltage variation determination unit 111 may be configured to check whether the first voltage stored in a previous ignition-off (IG off) state exists when the ignition is switched to the on (IG on) state.

When the first voltage stored in the previous ignition-off (IG off) state does not exist, the voltage variation determination unit 111 may be configured to initialize the first voltage (Ig off_ocv) and the second voltage (Ig on_ocv), and store, as the first voltage, an OCV measured in a next ignition-off (IG off) state.

The voltage variation determination unit 111 may be configured to store, as a second voltage, an open circuit voltage (OCV) measured in an ignition-on (IG on) state for each of the plurality of battery cells.

The voltage variation determination unit 111 may be configured to first determine whether a predetermined operating condition is satisfied and, if the condition is satisfied, store, as a second voltage, an open circuit voltage (OCV) measured in an ignition-on (IG on) state.

Here, the operating condition is intended to prevent misdiagnosis due to severe voltage deviations between battery cells under low state of charge (SOC) and low temperature conditions, and may be defined using a target SOC level (e.g., 20%) and a target temperature (e.g., 0° C).

The voltage variation determination unit 111 may be configured to store, as the second voltage, an open circuit voltage (OCV) measured under the predetermined operating condition, wherein the operating condition includes that, in the ignition-on (IG on) state, the state of charge (SOC) is at or above a target level (e.g., 20%) and the temperature is at or above a target temperature (e.g., 0° C).

The voltage variation determination unit 111 may be configured to determine the voltage variation for each battery cell among the plurality of battery cells based on a difference between the first voltage of each battery cell measured in an ignition-off (IG off) state and the second voltage of each battery cell measured in an ignition-on (IG on) state.

The battery cell determination unit 112 may be configured to determine at least some of the plurality of battery cells as diagnostic reference cells for detecting a micro internal short circuit, based on voltage variations determined for each of the plurality of battery cells.

For example, the battery cell determination unit 112 may be configured to determine, as an abnormal battery cell, a specific battery cell having the greatest voltage variation (voltage drop) among the plurality of battery cells and to determine the remaining battery cells, excluding the abnormal battery cell, as diagnostic reference cells for detecting a micro internal short circuit.

According to an exemplary embodiment of the present disclosure, diagnostic reference cells may be determined among a plurality of battery cells, so that a micro internal short circuit in each of the plurality of battery cells may be diagnosed based on the voltage variations of the diagnostic reference cells, excluding the abnormal battery cell. This is intended to improve diagnostic sensitivity compared to a case in which the voltage variation of the abnormal battery cell is also included.

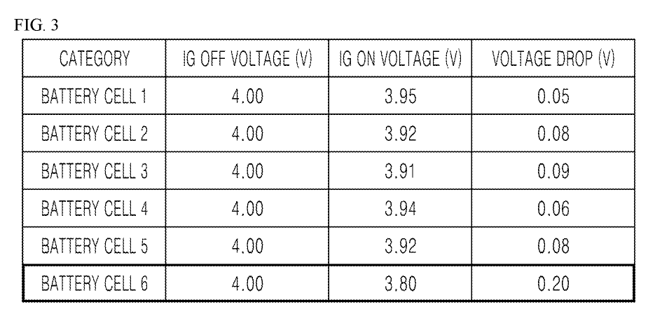

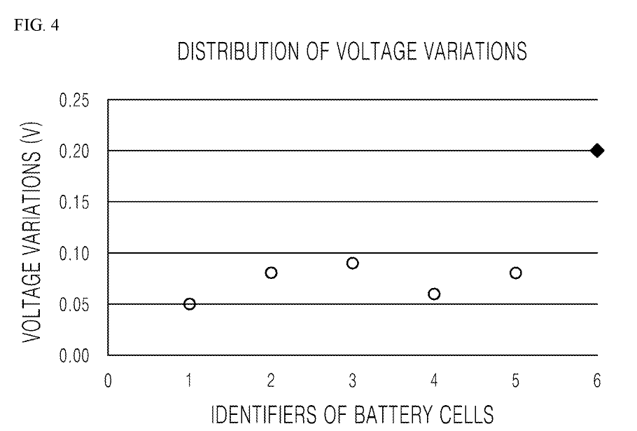

In this regard, FIG. 3 is a diagram exemplarily illustrating voltage variation values for a plurality of battery cells, according to an exemplary embodiment of the present disclosure. FIG. 4 is a diagram exemplarily illustrating the distribution of voltage variations for a plurality of battery cells, according to an exemplary embodiment of the present disclosure.

Referring to FIGS. 3 and 4, it may be seen that, among battery cells 1 to 6, battery cell 6 has the greatest voltage variation (0.2 V). In such a situation, battery cell 6, which has the greatest voltage variation, may be determined as an abnormal battery cell, and the remaining battery cells 1 to 5 may be determined as diagnostic reference cells for detecting a micro internal short circuit.

Meanwhile, according to an exemplary embodiment of the present disclosure, a method of determining, as an abnormal battery cell, a specific battery cell having the greatest voltage variation among the plurality of battery cells has been described. However, the embodiments of the present disclosure are not limited thereto. According to an exemplary embodiment, one or more battery cells may also be determined as abnormal battery cells when the voltage variation of an individual battery cell exceeds a predetermined threshold, or when the difference between the voltage variation of a battery cell and those of other battery cells exceeds the threshold.

The battery cell diagnosis unit 113 may be configured to diagnose a micro internal short circuit in each of the plurality of battery cells based on voltage variations of the diagnostic reference cells, after the diagnostic reference cells have been determined.

The battery cell diagnosis unit 113 may be configured to determine an average value of the voltage variations of the diagnostic reference cells and determine, for each battery cell, a difference between a voltage variation of each battery cell and the average value of the voltage variations of the diagnostic reference cells.

According to an exemplary embodiment of the present disclosure, a method of diagnosing a micro internal short circuit in each of a plurality of battery cells is described based on an average value of voltage variations of the diagnostic reference cells. However, embodiments of the present disclosure are not limited thereto. According to an exemplary embodiment, a method of diagnosing a micro internal short circuit in each of a plurality of battery cells may use, as a reference, a median value of the voltage variations of the diagnostic reference cells.

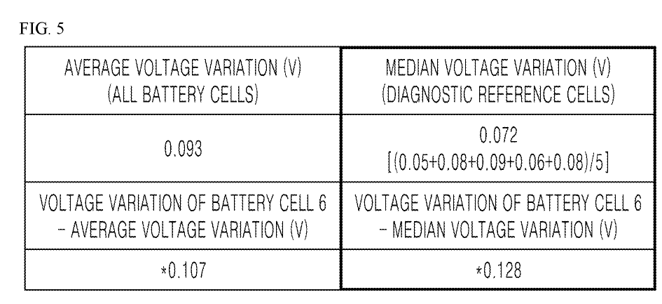

FIG. 5 is a diagram exemplarily illustrating an average value of voltage variations for diagnostic reference cells, according to an exemplary embodiment of the present disclosure.

FIG. 5 is a result based on the voltage variations of each battery cell shown in FIGS. 3 and 4.

Referring to FIG. 5, a difference may be observed between the average voltage variation (0.093 V) of all battery cells and the average voltage variation (0.070 V) of the diagnostic reference cells excluding an abnormal battery cell that has the greatest voltage variation.

The difference between the voltage variation (0.2V) of abnormal battery cell 6 and the average voltage variation (0.093V) of all battery cells is 0.107V. Similarly, the difference between the voltage variation (0.2V) of battery cell 6 and the average voltage variation (0.072V) of the diagnostic reference cells is 0.128V. Since a greater difference in voltage variation may enhance the sensitivity of diagnosing a micro internal short circuit, using the average value of the voltage variations of the diagnostic reference cells may result in improved diagnostic sensitivity.

The battery cell diagnosis unit 113 may be configured to determine, for each of the plurality of battery cells, a difference between the voltage variation of each battery cell and the average value of the voltage variations of the diagnostic reference cells, and to diagnose a micro internal short circuit in each battery cell based on a comparison between the determined difference and a diagnostic threshold (e.g., 3 mV).

For example, the battery cell diagnosis unit 113 may be configured to diagnose a battery cell as having a micro internal short circuit based on a difference between the voltage variation of the battery cell and the average value of the voltage variations of the diagnostic reference cells exceeding a diagnostic threshold (e.g., 3 mV), and on repeated detection, at least a target number of times (e.g., three times), of the difference exceeding the diagnostic threshold.

To this end, the battery cell diagnosis unit 110 may be configured to, whenever the ignition is switched from the off state to the on state, detect battery cells having differences between their voltage variation and the average value of the voltage variations of the diagnostic reference cells that exceeds a diagnostic threshold (e.g., 3 mV), and to accumulate and store the identifiers of the detected battery cells.

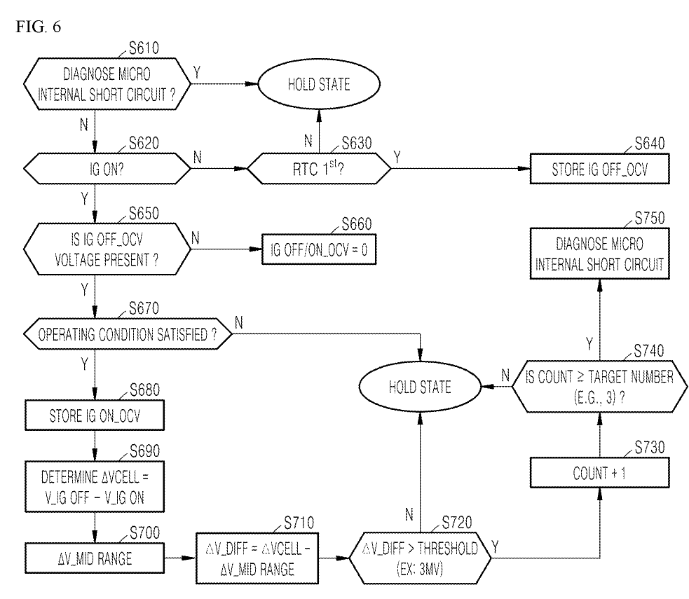

Hereinafter, a method for detecting a micro internal short circuit, according to an exemplary embodiment of the present disclosure, will be described with reference to FIG. 6. The method may be configured to be performed by the battery diagnosis apparatus 110 described above with reference to FIG. 2.

FIG. 6 is a flowchart illustrating a method for detecting a micro internal short circuit, according to an exemplary embodiment of the present disclosure.

In steps S610 to S640, the battery diagnosis apparatus 110 may be configured to store, as a first voltage (Ig off_ocv), an open circuit voltage (OCV) measured in an ignition-off (IG off) state for each of a plurality of battery cells.

For example, after the ignition is switched to off state (IG off), the battery diagnosis apparatus 110 may be configured to store, as the first voltage (IG off_ocv), the open circuit voltage (OCV) measured for each battery cell when the vehicle control unit (VCU) first wakes up (RTC 1st, Real Time Clock 1st) after being switched to the off state.

The point in time when the vehicle control unit (VCU) first wakes up (RTC 1st) after transitioning to the off state corresponds to a moment when battery polarization is minimized, and an open circuit voltage (OCV) is measured at this time to determine the battery's final charging voltage (V_finish). This helps prevent misdiagnosis in the micro internal short circuit detection logic due to voltage differences caused by battery polarization.

When the ignition is switched to on state (IG on), in S650, the battery diagnosis apparatus 110 may be configured to determine whether the first voltage (IG off_ocv) stored during the previous ignition-off (IG off) state exists.

When the first voltage (IG off_ocv) stored during the previous ignition-off (IG off) state does not exist, in S660, the battery diagnosis apparatus 110 may be configured to initialize the first voltage (IG off_ocv) and a second voltage (IG on_ocv), and to store, as the first voltage (IG off_ocv), an open circuit voltage (OCV) measured during a next ignition-off state.

In S670 and S680, the battery diagnosis apparatus 110 may be configured to store, as the second voltage (IG on_ocv), an open circuit voltage (OCV) measured in the ignition-on (IG on) state for each of the plurality of battery cells.

The battery diagnosis apparatus 110 may be configured to first determine whether a predetermined operating condition is satisfied, and if the condition is satisfied, store, as the second voltage (IG on_ocv), an open circuit voltage (OCV) measured in the ignition-on (IG on) state.

Here, the operating condition is intended to prevent misdiagnosis due to severe voltage deviations between battery cells under low state of charge (SOC) and low temperature conditions, and may be defined using a target SOC level (e.g., 20%) and a target temperature (e.g., 0° C).

The voltage variation determination unit 111 may be configured to store, as the second voltage (IG on_ocv), an open circuit voltage (OCV) measured under the predetermined operating condition, wherein the operating condition includes that, in the ignition-on (IG on) state, the state of charge (SOC) is at or above a target level (e.g., 20%) and the temperature is at or above a target temperature (e.g., 0° C).

In S690, for each of the plurality of battery cells, the battery diagnosis apparatus 110 may be configured to determine voltage variations (∆Vcell) for each battery cell as differences between a first voltage (IG off_ocv) of each battery cell measured in the ignition-off state and a second voltage of each battery cell measured in the ignition-on state.

When the voltage variations (∆Vcell) are determined for each battery cell, the battery diagnosis apparatus 110 may be configured to determine at least some of the plurality of battery cells as diagnostic reference cells for detecting a micro internal short circuit, based on the voltage variations (∆Vcell).

For example, the battery diagnosis apparatus 110 may be configured to determine, as an abnormal battery cell, a specific battery cell having the greatest voltage variation (voltage drop) among the plurality of battery cells and to determine the remaining battery cells, excluding the abnormal battery cell, as diagnostic reference cells for detecting a micro internal short circuit.

In one embodiment of the present disclosure, diagnostic reference cells are determined among a plurality of battery cells, so that a micro internal short circuit in each of the plurality of battery cells may be diagnosed based on the voltage variations of the diagnostic reference cells, excluding the abnormal battery cell. This is intended to improve diagnostic sensitivity compared to a case in which the voltage variation of the abnormal battery cell is also included.

Meanwhile, according to an exemplary embodiment of the present disclosure, a method of determining, as an abnormal battery cell, a specific battery cell having the greatest voltage variation among the plurality of battery cells has been described. However, the embodiments of the present disclosure are not limited thereto. According to an exemplary embodiment, one or more battery cells may also be determined as abnormal battery cells when the voltage variation of an individual battery cell exceeds a predetermined threshold, or when the difference between the voltage variation of a battery cell and those of other battery cells exceeds the threshold.

When the diagnostic reference cells are determined from the plurality of battery cells, the battery diagnosis apparatus 110 may be configured to diagnose a micro internal short circuit in each of the plurality of battery cells based on the voltage variations (∆Vcell) of the diagnostic reference cells.

In S700 and S710, the battery diagnosis apparatus 110 may be configured to determine an average value (∆Vcell_trimmean) of the voltage variations (∆Vcell) of the diagnostic reference cells, and determine a difference (V_diff) between the voltage variation (∆Vcell) of each of the plurality of battery cells and the average value (∆Vcell_trimmean) of the voltage variations of the diagnostic reference cells.

According to an exemplary embodiment of the present disclosure, the method for diagnosing a micro internal short circuit in each of the plurality of battery cells is described based on the average value (∆Vcell_trimmean) of voltage variations of the diagnostic reference cells. However, embodiments of the present disclosure are not limited thereto. According to another embodiment, a method for diagnosing a micro internal short circuit in each of a plurality of battery cells may use, as a reference, a median value of the voltage variations of the diagnostic reference cells.

When the differences (V_diff) are determined, in S720 to S750, the battery diagnosis apparatus 110 may be configured to compare the determined differences (V_diff) with a diagnostic threshold (e.g., 3 mV) and diagnose a micro internal short circuit in each of a plurality of battery cells based on the comparison result.

For example, the battery diagnosis apparatus 110 may be configured to diagnose a battery cell as having a micro internal short circuit based on the difference (V_diff) between the voltage variation (∆Vcell) of the battery cell and the average value (∆Vcell_trimmean) of the voltage variations of the diagnostic reference cells exceeding a diagnostic threshold (e.g., 3 mV), and on repeated detection, at least a target number of times (e.g., three times), of the difference exceeding the diagnostic threshold.

To this end, the battery diagnosis apparatus 110 may be configured to, whenever the ignition is switched from the off state (IG off) to the on state (IG on), detect battery cells having a difference (V_diff) between their voltage variation (∆Vcell) and the average value (∆Vcell_trimmean) of the voltage variations of the diagnostic reference cells that exceeds a diagnostic threshold (e.g., 3 mV), and to accumulate and store the identifiers of the detected battery cells.

As used in the present disclosure (especially in the appended claims), the terms "a/an" and "the" include both singular and plural referents, unless the context clearly states otherwise. Also, it should be understood that any numerical range recited in the present disclosure is intended to include all sub-ranges subsumed therein (unless expressly indifcated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof ("for example", "such as") are merely to describe the present disclosure in greater detail. Therefore, it should be understood that the scope of the present disclosure is not limited to the example embodiments described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the example embodiments described above, and rather intended to include the following appended claims, and all modifications, equivalents, and alternatives falling within the spirit and scope of the following claims.

What is claimed is:

1. A battery diagnosis apparatus comprising:
a computing device comprising a battery cell diagnosis unit configured to diagnose a micro internal short circuit in one or more battery cells, of a plurality of battery cells, when:
a difference between a voltage variation of a battery cell, of the plurality of battery cells, and an average voltage variation value of one or more diagnostic reference battery cells exceeds a diagnostic threshold value.

2. The battery diagnosis apparatus of claim 1, wherein the diagnostic threshold is 3mV.

3. The battery diagnosis apparatus of claim 2, wherein the battery cell diagnosis unit is configured to diagnose a battery cell, of the plurality of battery cells as having a micro internal short circuit, when a difference between a voltage variation of the battery cell, of the plurality of battery cells, and the average voltage variation value of the one or more diagnostic reference battery cells exceeding the diagnostic threshold value is detected at least a target number of times.

4. The battery diagnosis apparatus of claim 1, further comprising the plurality of battery cells.

5. The battery diagnosis apparatus of claim 4, wherein the reference battery cells comprise diagnostic reference cells comprising one or more remaining battery cells, other than an abnormal battery cell, that has a greatest voltage variation among the plurality of battery cells.

6. The battery diagnosis apparatus of claim 1, wherein the computing device further comprises a voltage variation determination unit configured to:
determine a voltage variation for each battery cell as a difference between a first voltage of each battery cell, which comprises an open circuit voltage (OCV) measured in an ignition-off (IG off) state, and a second voltage of each battery cell, which comprises an open circuit voltage (OCV) measured in an ignition-on (IG on) state.

7. The battery diagnosis apparatus of claim 6, wherein the voltage variation determination unit is configured to store, as the first voltage, an OCV measured when the vehicle control unit (VCU) first wakes up after transitioning to an off state in response to ignition-off (IG off).

8. The battery diagnosis apparatus of claim 6, wherein the voltage variation determination unit is configured to initialize the first voltage and the second voltage based on a determination, in the ignition-on (IG on) state, that the OCV stored as the first voltage does not exist, and to store, as the first voltage, an OCV measured in a next ignition-off (IG off) state.

9. The battery diagnosis apparatus of claim 6, wherein the voltage variation determination unit is configured to store, as the second voltage, an OCV measured in an ignition-on (IG on) state, based on a state of charge (SOC) being equal to or above a target level and a temperature being equal to or above a target temperature.

10. A battery diagnosis apparatus comprising:
a computing device comprising a processor and a memory, wherein the memory is configured to store instructions that, when executed by the processor, are configured to cause the processor to:
diagnose a micro internal short circuit in one or more battery cells, of a plurality of battery cells, when:
a difference between a voltage variation of a battery cell, of the plurality of battery cells, and an average voltage variation value of one or more diagnostic reference battery cells exceeds a diagnostic threshold value.

11. The battery diagnosis apparatus of claim 10, further comprising the plurality of battery cells.

12. The battery diagnosis apparatus of claim 10, wherein the computing device is configured to diagnose a battery cell, of the plurality of battery cells as having a micro internal short circuit, when a difference between a voltage variation of the battery cell, of the plurality of battery cells, and the average voltage variation value of the one or more diagnostic reference battery cells exceeding the diagnostic threshold value is detected at least a target number of times.

13. A method for detecting a micro internal short circuit performed by a battery diagnosis apparatus, the method comprising:
using a computing device comprising a processor and a memory, diagnosing a micro internal short circuit in one or more battery cells, of a plurality of battery cells, when:
a difference between a voltage variation of a battery cell, of the plurality of battery cells, and an average voltage variation value of one or more diagnostic reference battery cells exceeds a diagnostic threshold value.

14. The method of claim 13, wherein the diagnostic threshold is 3mV.

15. The method of claim 14, wherein the diagnosing comprises diagnosing a battery cell among the plurality of battery cells as having a micro internal short circuit, when a difference between a voltage variation of the battery cell, of the plurality of battery cells, and the average voltage variation value of the one or more diagnostic reference battery cells exceeding the diagnostic threshold value is detected at least a target number of times.

16. The method of claim 13, wherein the reference battery cells comprise diagnostic reference cells comprising as remaining battery cells, other than an abnormal battery cell, that has a greatest voltage variation among the plurality of battery cells.

17. The method of claim 13, further comprising, using the computing device, determining a voltage variation for each battery cell as a difference between a first voltage of each battery cell, which comprises an open circuit voltage (OCV) measured in an ignition-off (IG off) state, and a second voltage of each battery cell, which comprises an OCV measured in an ignition-on (IG on) state.

18. The method of claim 17, wherein the first voltage comprises an OCV measured when a vehicle control unit (VCU) first wakes up after transitioning to an off state in response to ignition-off (IG off).

19. The method of claim 17, wherein the first voltage comprises an OCV measured in a next ignition-off (IG off) state, based on a determination, in the ignition-on (IG on) state, that the OCV stored as the first voltage does not exist.

20. The method of claim 17, wherein the second voltage comprises an OCV measured in the ignition-on (IG on) state, based on a state of charge (SOC) being equal to or above a target level and a temperature being equal to or above a target temperature.
